(19) United States
(12) Patent Application Publication
(10) Pub. No.: US 2003/0013025 A1
(43) Pub. Date: Jan. 16, 2003

(54) Version management circuit, and method of manufacturing the version management circuit

(76) Inventors: Hidekazu Tawara, Tokyo (JP); Shuji Kodama, Tokyo (JP)

Correspondence Address: Platon N. Mandros, BURNS, DOANE, SWECKER & MATHIS, L.L.P., P.O. Box 1404, Alexandria, VA, 22313-1404, US

(21) Appl. No.: 10/013,651

(22) Filed: Dec. 13, 2001

(30) Foreign Application Priority Data
Jul. 10, 2001 (JP) 2001-209852

(51) Int. Cl. H01L 23/544; G03C 5/00

(52) U.S. Cl. 430/20; 257/797

(57) ABSTRACT

The version management circuit comprises a plurality of mask revision state output circuits and an EXOR circuit. Each mask revision state output circuit selectively outputs a low or high logical level by changing only one mask. The EXOR circuit conducts an EXOR arithmetic operation to a level output from the mask revision state output circuits and outputs the result as a register value. Thus, the version management circuit can be changed and the version code can be rewritten by revising only one mask even if the mask is other than a mask related to a circuit required to be changed.

### FIELD OF THE INVENTION

The present invention relates to a circuit for managing the circuit revision history of a semiconductor integrated circuit and a method of manufacturing such a circuit.

### BACKGROUND OF THE INVENTION

A semiconductor integrated circuit such as an IC chip is normally shipped in a state in which identification numbers such as a type code for identifying the type of the IC chip and a manufacturing code for identifying a manufacturing period are allotted to the IC chip. Besides these identification numbers, a version code indicating that the same product as this IC chip was shipped but differs from the IC chip in circuit configuration by making a revision is allotted to the IC chip.

These identification numbers including the above-stated version code are often written to a part of a storage circuit constituting the IC chip so that the numbers can be read as IC identification information. Especially the version code can be read from a version management circuit referred to as “version management register” which can manage the revision history of the IC chip.

For example, if a defect is discovered after the shipment of the IC chip, the version code is used to grasp the circuit configuration of the defective IC chip, to locate the cause of the defect based on the difference in circuit configuration between before and after a revision and also used as a management code if the IC chip is further revised.

However, since the revision of the IC chip includes not only the revision of a circuit part which carries out circuit operation but also the revision of the above-stated version code, it is necessary to change the configuration of the version management register used as a mask ROM. As IC chips have become multifunctional and higher in integration in recent years, in particular, it is necessary to employ many masks through complicated procedures in the photolithographic step of manufacturing the IC chips. As a result, even if only one mask is to be changed so as to revise the circuit related to the circuit operation, it is required to change many other masks related to the formation of the version management register, disadvantageously hampering manufacturing efficiency.

### SUMMARY OF THE INVENTION

It is an object of the present invention to provide a circuit capable of revising the version code of a semiconductor integrated circuit only by changing minimum number of masks. It is another object of this invention to provide a method of manufacturing the circuit according to the present invention.

The version management circuit according to one aspect of this invention is formed by sharing a part of a photolithographic technique by which a semiconductor integrated circuit is formed. The version management circuit holds revision information on the semiconductor integrated circuit. The version management circuit comprises a plurality of mask revision state output units which change different output values according to changes by each being formed by changing a part of a pattern of one of a plurality of masks used in the photolithographic technique to a pattern having a masked part or a non-masked part; and a revision information generation unit which generates the revision information on the semiconductor integrated circuit based on the output values output from the plurality of mask revision state output units.

According to this invention, the revision information on the semiconductor integrated circuit can be managed by the version management circuit formed by changing only the pattern of one of a plurality of masks used in the photolithographic technique.

The method of manufacturing the version management circuit according to another aspect of this invention is a method of manufacturing the version management circuit that is formed by sharing a part of a photolithographic technique by which a semiconductor integrated circuit is formed. The version management circuit holds revision information on the semiconductor integrated circuit. The method comprise a mask change step of changing a part of a pattern of any one of a plurality of masks used in the photolithographic technique to one of a masked part and a non-masked part, the part determining an output value of the version management circuit; and a version management circuit formation step of forming the version management circuit using the mask changed in the mask change step.

According to this invention, it is possible to manufacture a version management circuit capable of changing the version information on the semiconductor integrated circuit by changing only the pattern of one of a plurality of masks used in the photolithographic step.

Other objects and features of this invention will become apparent from the following description with reference to the accompanying drawings.

### BRIEF DESCRIPTION OF THE DRAWINGS

FIG. 1 is a schematic block diagram of a version management circuit in the first embodiment according to the present invention;

FIG. 2 is an explanatory view for the operation of the version management circuit in the first embodiment;

FIG. 3 shows an example of a mask revision state output circuit capable of changing an output value by changing only a mask in an element isolation region formation step;

FIG. 4A and FIG. 4B are layout cross-sectional views for describing the structure of the mask revision state output circuit changed by the mask in the element isolation region formation step;

FIG. 5 shows an example of a mask revision state output circuit capable of changing an output value by changing only a mask in a contact hole formation step;

FIG. 6A and FIG. 6B are layout cross-sectional views for describing the structure of the mask revision state output circuit changed by the mask in the contact hole formation step;

FIG. 7 shows another example of a mask revision state output circuit capable of changing an output value by changing only a mask in the contact hole formation step;

FIG. 8A and FIG. 8B are layout top views for describing another structure of the mask revision state output circuit changed by the mask in the contact hole formation step;

FIG. 9 shows an example of a mask revision state output circuit capable of changing an output value by changing only a mask in a wiring formation step;

FIG. 10A and FIG. 10B are layout cross-sectional views for describing the structure of a mask revision state output circuit changed by the mask in the wiring formation step;

FIG. 11 shows another example of a mask revision state output circuit capable of changing an output value by changing only a mask in the wiring formation step;

FIG. 12A and FIG. 12B are layout top views for describing another structure of the mask revision state output circuit changed by the mask in the wiring formation step;

FIG. 13 is a schematic block diagram of a version management circuit in the second embodiment according to the present invention; and

FIG. 14 is an explanatory view for the operation of the version management circuit in the second embodiment.

### DESCRIPTION OF THE PREFERRED EMBODIMENTS

Embodiment/s of a version management circuit and a manufacturing method therefor according to the present invention will be described hereinafter in detail with reference to the drawings. It should be noted that the present invention is not limited to the following embodiments.

To begin with, a version management circuit and its method of manufacturing according to the first embodiment of the present invention will be explained. The version management circuit in the first embodiment is characterized in that the revision of the version management circuit is executed simultaneously during the revision of masks used in respective steps (an element isolation region formation step, a contact hole formation step and a wiring formation step) for manufacturing a semiconductor integrated circuit while changing minimum number of masks.

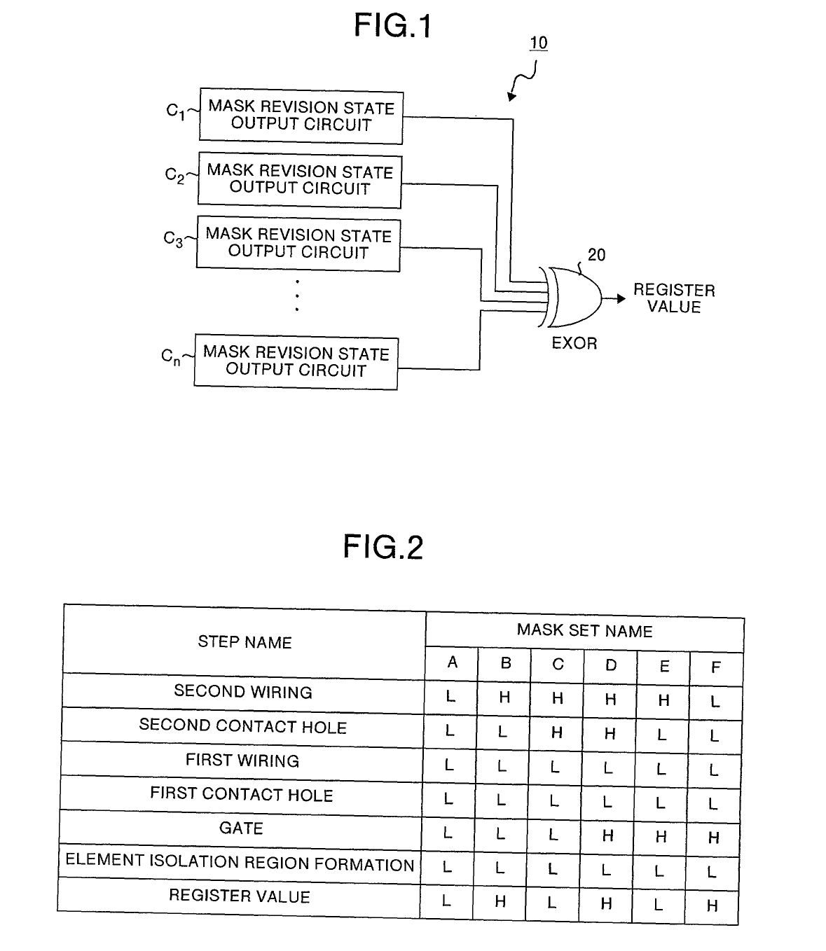

FIG. 1 is a schematic block diagram showing the version management circuit in the first embodiment. As shown in FIG. 1, the version management circuit 10 consists of a plurality of mask revision state output circuits C₁ to Cₙ and an EXOR circuit 20. The mask revision state output circuits C₁ to Cₙ are circuits each reformed by the change of only one mask and thereby capable of selectively outputting a logical level “L” (low) or “H” (high). For example, the mask revision state output circuit C₁ is a circuit outputting a logical level “L” or “H” according to the change of a mask for forming the element isolation region of a transistor, i.e., according to the formation state of the element isolation region of the mask revision state output circuit C₁ itself.

Likewise, the mask revision state output circuit C₂, for example, is a circuit outputting a logical level “L” or “H” according to the change of a mask for forming the gate electrode of the transistor. The mask revision state output circuits C₃ to Cₖ₊₂ are circuits each outputting a logical level “L” or “H” according to the change of a mask for k layers constituting the contact hole of the transistor. The mask revision state output circuits Cₖ₊₃ to Cₙ are circuits each outputting a logical level “L” or “H” according to the change of a mask for (k+1) layers forming the wirings of the transistor.

In addition, the EXOR circuit 20 conducts an EXOR arithmetic operation to an output value output from each of the above-stated mask revision state output circuits C₁ to Cₙ and outputs the operation result as a register value.

Operation of the version management circuit according to the first embodiment will now be described with reference to FIG. 2. The table of FIG. 2 specifically shows a case where this version management circuit is applied to a 2-layer, 1-poly CMOS device. To manufacture the 2-layer, 1-poly CMOS device, a second wiring mask, second contact hole mask, first wiring mask, first contact hole mask, gate formation mask, and an element isolation region formation mask are used.

Here, description will be given while taking a case of revising the second wiring mask, the second contact hole mask, the gate formation mask, the second contact hole mask and the second wiring mask in this order as an example and assuming that the name of an initial mask set is A followed by B, C, D, E and F which are the names of mask sets for which following revisions are executed.

It is also assumed that the mask revision state output circuits C₁, C₂, C₃, C₄, C₅ and C₆ correspond to circuits which output values are determined by the changes of only the second wiring mask, the second contact hole mask, the first wiring mask, the first contact hole mask, the gate formation mask and the element isolation region formation mask, respectively.

Assume that the initial mask set (or mask set A) to which no revision is made, if the logical levels of the output values of the mask revision state output circuits C₁ to C₆ are all “L”, then the EXOR circuit 20 receives the output values of the mask revision state output circuits C₁ to C₆ and consequently outputs a logical level “L” as a register value. Next, if it becomes necessary to revise the semiconductor integrated circuit, the mask pattern of a part of the second wiring mask which part constitutes at least the mask revision state output circuit C₁ is changed from the state of the mask set A (to that of the mask set B), thereby changing the logical level of the output value of the mask revision state output circuit C₁ from “L” to “H”. As a result, the EXOR circuit 20 outputs a logical level “H” as a register value.

If it becomes further necessary to revise the semiconductor integrated circuit, the mask pattern of a part of the second contact hole mask which part constitutes at least the mask revision state output circuit C₂ is changed from the state of the mask set B described above (to that of the mask set C), thereby changing the logical level of the output value of the mask revision state output circuit C₂ from “L” to “H”. As a result, the EXOR circuit 20 outputs a logical level “L” as a register value.

Further, if it become necessary to revise the semiconductor integrated circuit, the mask pattern of apart of the gate formation mask which part constitutes at least the mask revision state output circuit C₃ is changed from the state of the mask set C (to that of the mask set D), thereby changing the logical level of the output value of the mask revision state output circuit C₃ from “L” to “H”. As a result, the EXOR circuit 20 outputs a logical level “H” as a register value.

Likewise, the patterns of masks in the mask sets D, E and F are changed so as to obtain the respective logical levels shown in FIG. 2, thereby making it possible to change register values. By referring to the changed register values, it is possible to discriminate mask sets before revisions from those after revisions.

A concrete configuration of the mask revision state output circuits C₁to Cₙ will now be explained. Specifically, description will be given to the mask revision state output circuit capable of changing an output value by changing only a mask in the element isolation region formation step, the mask revision state output circuit capable of changing an output value by changing only a mask in the gate formation step, the mask revision state output circuit capable of changing an output value by changing only a mask in the contact hole formation step, and the mask revision state output circuit capable of changing an output value by changing only a mask in the wiring formation step in this order.

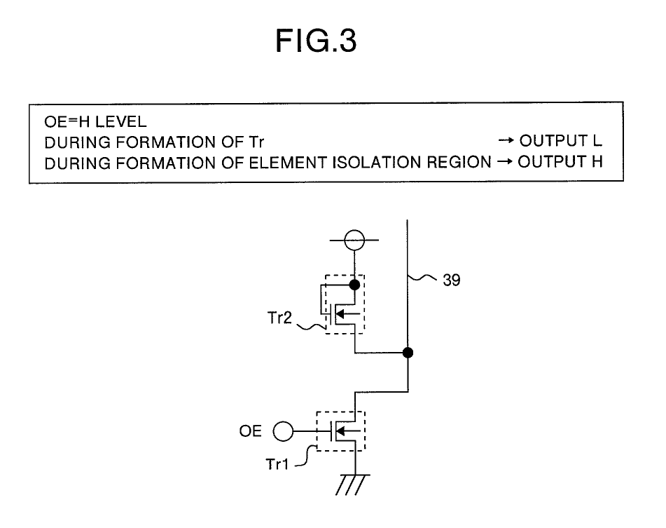

FIG. 3 shows an example of configuration of a mask revision state output circuit capable of changing an output value by changing only a mask in the element isolation region formation step. In FIG. 3, the mask revision state output circuit comprises an NMOS transistor Tr1 having a source that is grounded and a gate that receives an enable signal, and a load NMOS transistor Tr2 having a drain connected to the drain of the NMOS transistor Tr1 and a gate and a source supplied with a power supply voltage. Also, the output value of this mask revision state output circuit is obtained from an output line 39 connected to the drain of the NMOS transistor Tr1. It is noted that the load NMOS transistor Tr2 functions as a pull-up resistance.

Accordingly, if an enable signal having a logical level “H” is input into the OE (Output Enable) terminal of this mask revision state output circuit, the NMOS transistor Tr1 is turned on and a logical level “L” is output from the output line 39. Conversely, if an enable signal having a logical level “L” is input into the OE terminal, the NMOS transistor Tr1 is turned off and a logical level “H” is output from the output line 39.

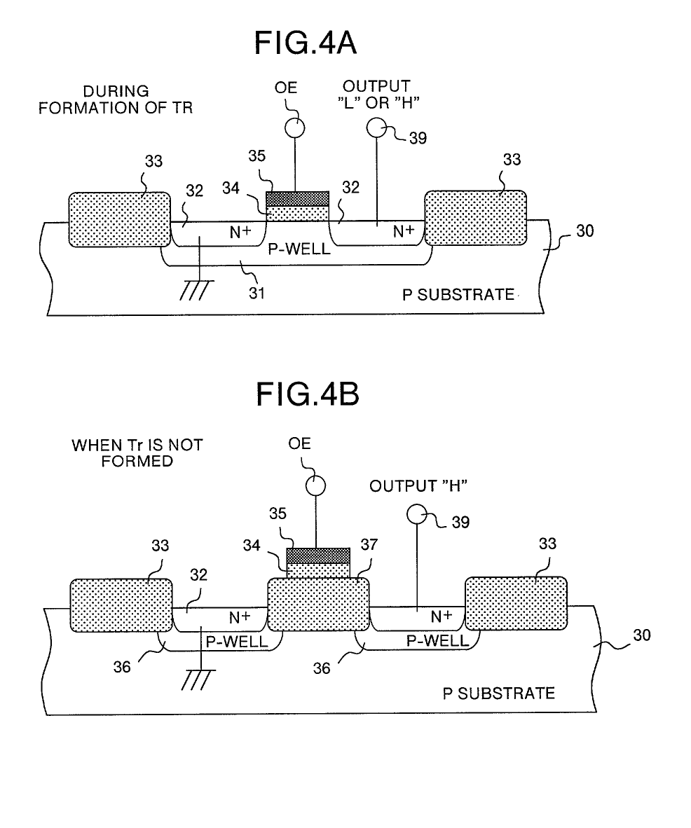

FIG. 4A and FIG. 4B are cross-sectional views of the NMOS transistor Tr1. FIG. 4A shows a structure for allowing the NMOS transistor Tr1 to operate as an ordinary MOS transistor as described above. As shown in FIG. 4A, to constitute the NMOS transistor Tr1, a P-well region 31 is formed between element isolation regions (or oxide films) 33 formed on a P substrate 30, and a gate insulating film 34 and a gate electrode 35 are built up on the P-well 31. Also, N+ diffused regions 32 are formed on the P-well region 31 and between the buildup structure of the gate insulating film 34 and the gate electrode 35 and the element isolation regions 33, respectively. Namely, masks are used to form an ordinary NMOS transistor having the structure shown in FIG. 4A.

If it is assumed that the NMOS transistor Tr1 shown in FIG. 3 does not function as a MOS transistor, a logical level “H” is output from the output line 39 irrespectively of the logical level input into the OE terminal. In case of this mask revision state output circuit, therefore, as shown in FIG. 4B, an element isolation region 37 is formed under the buildup structure of the gate insulating film 34 and the gate electrode 35, thereby invalidating the NMOS transistor Tr1. To be specific, the pattern of the mask in the element isolation region formation step is changed to such a pattern that an element isolation region is also formed at a position at which the gate insulating film 34 is arranged.

By changing so, divided P-well regions 36 are formed in a single MOS transistor. Even so, since the NMOS transistor Tr1 does not function as a MOS transistor, a logical level “H” is always output from the output line 39. As can be seen, the output value of the mask revision state output circuit can be changed by changing only the mask in the element isolation region formation step.

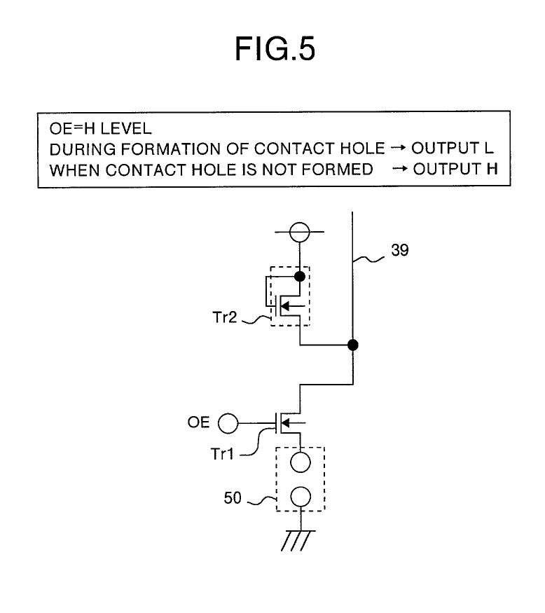

FIG. 5 shows an example of a mask revision state output circuit capable of changing an output value by changing only a mask in the contact hole formation step. It is noted that the circuit diagram shown in FIG. 5 is the same as that shown in FIG. 3. However, in case of the mask revision state output circuit in FIG. 5, it is determined whether or not the source of the NMOS transistor Tr1 and a GND line are electrically connected or not in the connection region 50 between the source of the NMOS transistor Tr1 and a GND line in the circuit shown in FIG. 5.

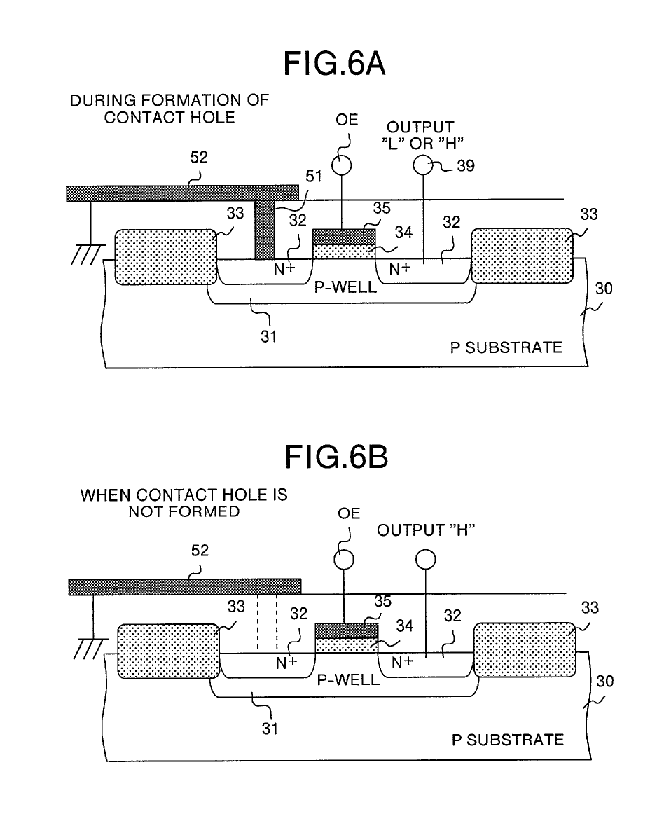

FIG. 6A and FIG. 6B are cross-sectional views for describing the structure of the NMOS transistor Tr1 shown in FIG. 5. It is noted that the elements in FIG. 6A and FIG. 6B that perform same or similar functions as those in FIG. 4A and FIG. 4B have been denoted by the same reference symbols and their explanation is omitted to avoid simple repetition of explanation. According to a structure shown in FIG. 6A, a wiring layer 52 connected to a GND line and a contact hole 51 connecting a source region to the wiring layer 52 are provided so as to ground N+ diffused regions 32 functioning as the source region. Namely, a mask for forming the contact hole 51 shown in FIG. 6A is used in the contact hole formation step.

If the source of the NMOS transistor Tr1 shown in FIG. 5 is not electrically connected to the GND line in the connection region 50, the NMOS transistor Tr1 does not function as an MOS transistor and a logical level “H” is output from the output line 39 irrespectively of the logical level input into the OE terminal. Accordingly, in case of this mask revision state output circuit, as shown in FIG. 6B, the contact hole 51 for electrically connecting the grounded wiring layer 52 to the source region is not formed, thereby invalidating the NMOS transistor Tr1. To be specific, the pattern of the mask in the contact hole formation step is changed to a pattern on which the part of the contact hole 51 is masked.

By thus changing the mask, the source of the NMOS transistor Tr1 is in a floating state, with the result that the NMOS transistor Tr1 does not function as an MOS transistor and that a logical level “H” is output from the output line 39. On the other hand, if the mask in the contact hole formation step has a pattern on which the part of the contact hole 51 is not masked, the source regions are grounded as shown in FIG. 6A and the NMOS transistor Tr1 functions as an ordinary transistor. As can be seen, it is possible to change the output value of the mask revision state output circuit by changing only the mask in the contact hole formation step.

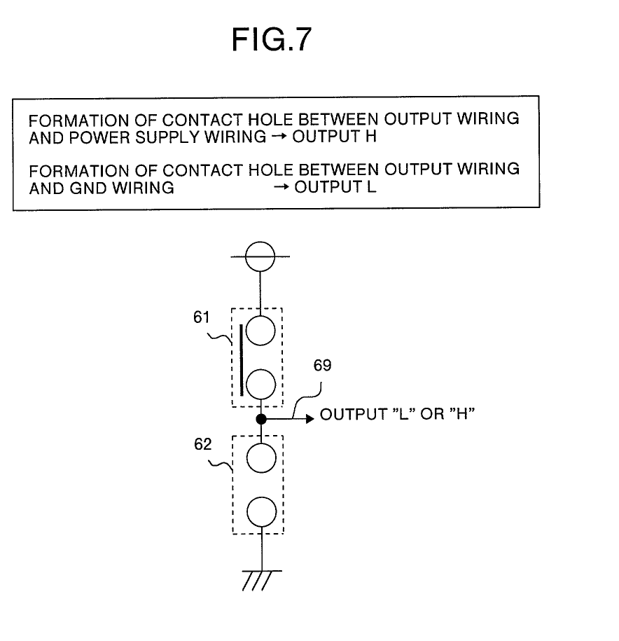

FIG. 7 shows another example of a mask revision state output circuit capable of changing an output value by changing only a mask in the contact hole formation step. The mask revision state output circuit shown in FIG. 7 consists of a connection region 61 determining a contact state between a power supply voltage line and an output line 69 and a connection region 62 determining a connection state between a GND line and the output line 69.

The connection states of these connection regions 61 and 62 are, in particular, complementary. If the connection region 61 connects the power supply voltage line to the output line 69, the connection region 62 does not connect the GND line to the output line 69. Conversely, if the connection region 61 does not connect the power supply voltage line to the output line 69, the connection region 62 connects the GND line to the output line 69.

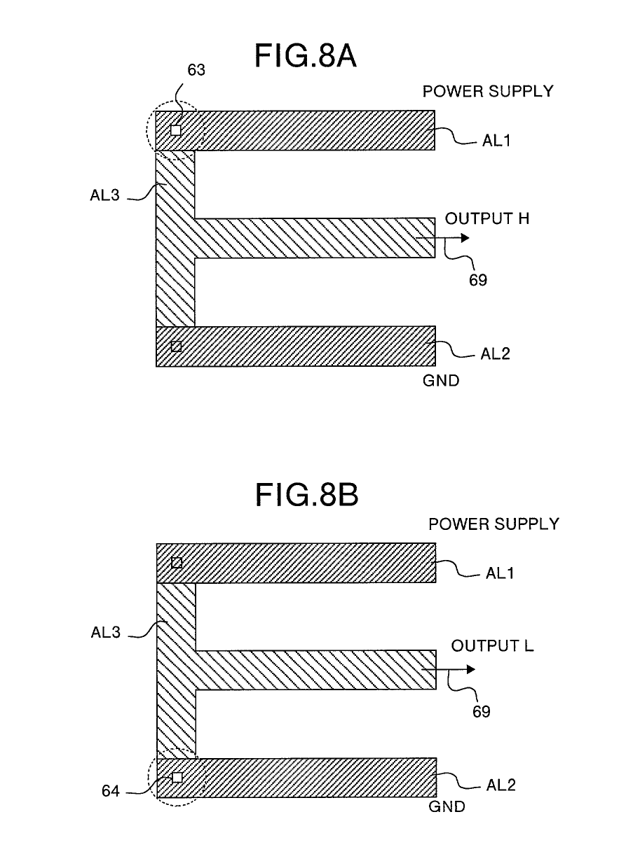

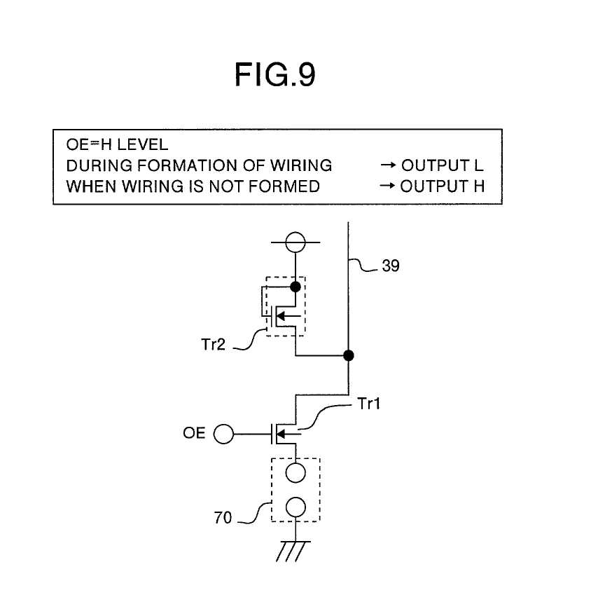

FIG. 8A and FIG. 8B are layout top views for describing the structure of the mask revision state output circuit shown in FIG. 7. To simplify description, it is assumed that a power supply wiring AL1 and a GND wiring AL2 are located on the same layer and an output wiring AL3 corresponding to the output line 69 shown in FIG. 7 is located on a lower layer. The buildup relationship among the power supply wiring AL1, the GND wiring AL2 and the output wiring AL3 should not be limited to that shown in FIG. 8A and FIG. 8B.

First, as shown in FIG. 8A, using, as a mask in the contact hole formation step, a mask having a pattern on which the part of a contact hole 63 is not masked, the contact hole 63 is formed and the power supply wiring AL1 and the output wiring AL3 are electrically connected to each other. It is noted, however, that a contact hole electrically connecting the GND line AL2 to the output wiring AL3 is not formed with this mask. That is, the connection region 61 shown in FIG. 7 is in a connecting state while the connection region 62 is in a non-connecting state. Eventually, the mask revision state output circuit formed by using this mask outputs a logical level “H” from the output line 69.

Also, as shown in FIG. 8B, using, as a mask in the contact hole formation step, a mask having a pattern on which the part of a contact hole 64 is not masked, the contact hole 64 is formed and the GND wiring AL2 and the output wiring AL3 are electrically connected to each other. It is noted, however, that a contact hole electrically connecting the power supply wiring AL1 to the output wiring AL3 is not formed with this mask. That is, the connection region 61 shown in FIG. 7 is in a non-connecting state while the connecting region 62 is in a connecting state. Eventually, the mask revision state output circuit formed by using this mask outputs a logical level “L” from the output line 69.

FIG. 9 shows an example of a mask revision state output circuit capable of outputting an output value by changing only a mask in the wiring formation step. It is noted that the circuit diagram shown in FIG. 9 is the same as that shown in FIG. 3. However, in case of the mask revision state output circuit shown in FIG. 9, it is determined whether or not the source of an NMOS transistor Tr1 is electrically connected to a GND line in the connection region 70 between the source of the NMOS transistor Tr1 and the GND line.

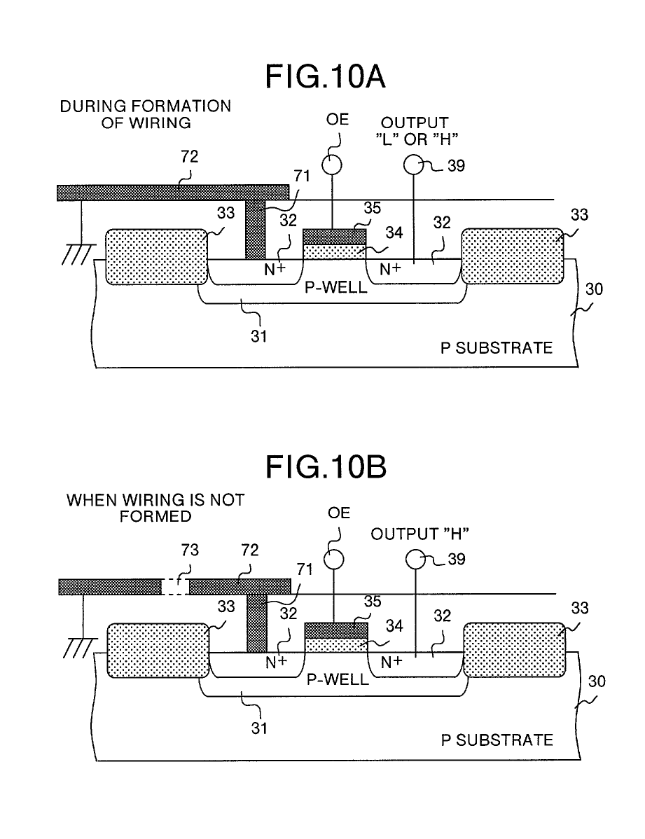

FIG. 10A and FIG. 10B are cross-sectional views for describing the structure of the NMOS transistor Tr1 shown in FIG. 9. It is noted that the elements in FIG. 10A and FIG. 10B that perform same or similar functions as those in FIG. 4A and FIG. 4B have been denoted by the same reference symbols and their explanation is omitted to avoid simple repetition of explanation. According to a structure shown in FIG. 10A, a wiring layer 72 connected to the GND line and a contact hole 71 connecting a source region to the wiring layer 72 are provided so as to ground N+ diffused regions 32 functioning as the source region. Namely, a mask for forming the wiring layer 72 shown in FIG. 10A is used in the wiring formation step.

If the source of the NMOS transistor Tr1 shown in FIG. 9 is not electrically connected to the GND line in a connection region 70, the NMOS transistor Tr1 does not function as a transistor and a logical level “H” is output from an output line 39 irrespectively of the logical level input into an OE terminal. Accordingly, in case of this mask revision state output circuit, as shown in a cutoff section 73 in FIG. 10B, the grounded wiring layer 72 is electrically cut off, thereby invalidating the NMOS transistor Tr1. To be specific, the pattern of a mask in the wiring formation step is changed to a pattern on which the cutoff section 73 of the wiring layer 72 is masked.

By thus changing the mask, the source of the NMOS transistor Tr1 is in a floating state, with the result that the NMOS transistor Tr1 does not function as an MOS transistor and a logical level “H” is output from the output line 39. On the other hand, if the mask in the wiring formation step has a pattern on which the part of the cutoff section 73 is not masked, the source region is grounded as shown in FIG. 10A and the NMOS transistor Tr1 functions as an ordinary MOS transistor. As can be seen, it is possible to change the output value of the mask revision state output circuit by changing only the mask in the wiring formation step.

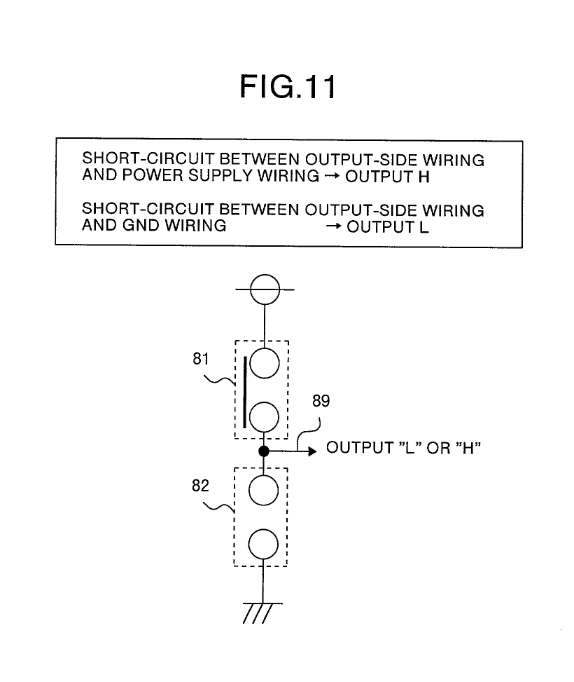

FIG. 11 shows another example of the mask revision state output circuit capable of outputting an output value by changing only a mask in the wiring formation step. The mask revision state output circuit shown in FIG. 11 consists of a connection region 81 determining the connection state between a power supply voltage line and an output line 89 and a connection region 82 determining the connection sate between a GND line and the output line 89.

The connection states of these connection regions 81 and 82 are, in particular, complementary. If the connection region 81 connects the power supply voltage line to the output line 89, the connection region 82 does not connect the GND line to the output line 89. Conversely, if the connection region 81 does not connect the power supply voltage line to the output line 89, the connection region 82 connects the GND line to the output line 89.

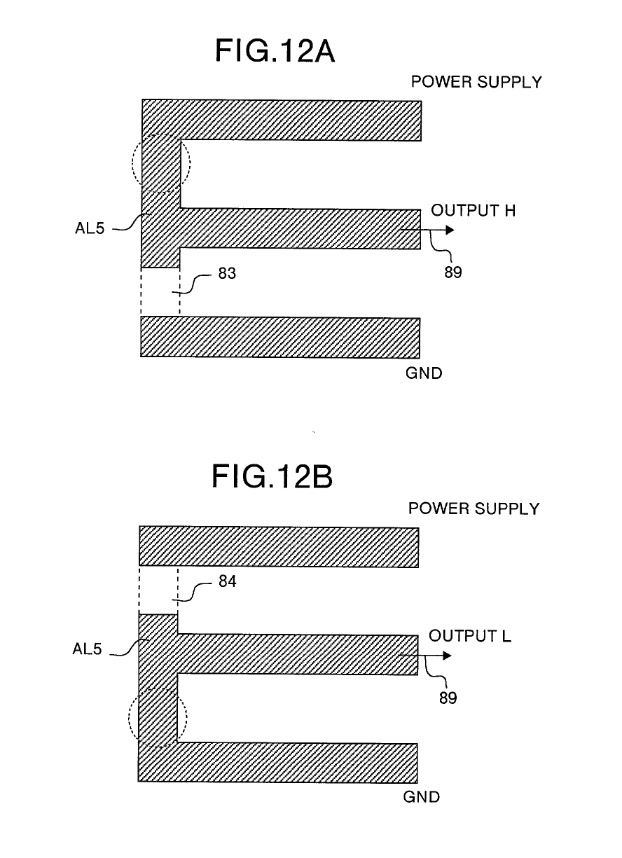

FIG. 12A and FIG. 12B are layout top views for describing the structure of the mask revision state output circuit shown in FIG. 11. Wiring layer AL5 is a metal wiring coupling a power supply wiring, a GND wiring and an output wiring with one another on the same layer and having such a shape that apart of the wiring is cut off as will be described later.

First, as shown in FIG. 12A, using, as a mask in the wiring formation step, a mask having a pattern on which the part of a cutoff region 83 is masked, the wiring layer AL5 is formed to electrically connect the power supply wiring to the output wiring. Namely, the connection region 81 shown in FIG. 11 is in a connecting state while the connection region 82 is in a non-connecting state. Eventually, the mask revision state output circuit formed by using this mask outputs a logical level “H” from the output line 89.

Moreover, as shown in FIG. 12B, using, as a mask in the wiring formation step, a mask having a pattern on which the part of the cutoff region 84 is masked, the wiring layer AL5 is formed to electrically connect the GND wiring to the output wiring. Namely, the connection region 81 shown in FIG. 11 is in a non-connecting state and the connection region 82 is in a connecting state. Eventually, the mask revision state output circuit formed by using this mask outputs a logical level “L” from the output line 89.

As stated so far, according to the version management circuit and the manufacturing method therefor in the first embodiment, it is possible to change the version management circuit, to rewrite a version code by revising only a mask related to a circuit which is required to be changed or by revising only one mask even if the mask is not related to the circuit which is required to be changed, and to thereby reduce mask cost, compared with a case where the conventional version management register is realized by using an ROM or the like, so that it is necessary to always revise a mask in a step related to the ROM even if a mask in a step unrelated to the ROM is revised.

Next, a version management circuit and its method of manufacturing according to the second embodiment of the present invention will be explained. In the first embodiment, since the value output from each mask revision state output circuit stated above is one bit, it is possible to discriminate the mask sets before revisions from those after revision but impossible to specify the mask sets. The version management circuit and the manufacturing method therefor in the second embodiment are, by contrast, characterized in that output values of plural bits are obtained from each mask revision state output circuit to thereby make it possible to specify a mask set during a revision. To simplify description, it is assumed that output values of three bits indicating a mask revision state are output from each mask revision state output circuit.

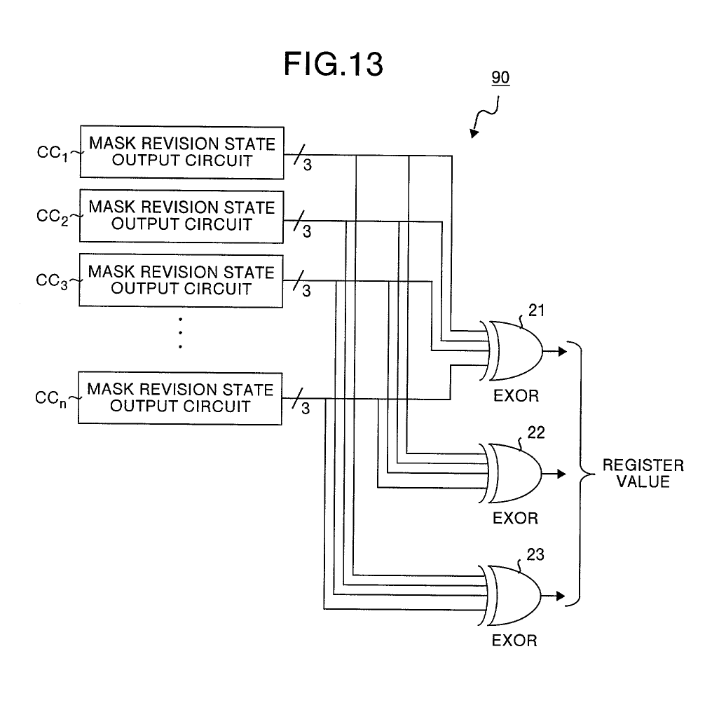

FIG. 13 is a schematic block diagram showing a version management circuit according to the second embodiment. As shown in FIG. 13, the version management circuit 90 comprises a plurality of mask revision state output circuits CC₁ to CCₙ and three EXOR circuits 21, 22 and 23. Each of the mask revision state output circuits CC₁ to CCₙ has a plurality of constitutions of the mask revision state output circuits described in the first embodiment in the circuit, thereby making it possible to selectively output three bits. For example, the mask revision state output circuit CC₁ has three circuits shown in FIG. 3. By changing a mask for forming the element isolation region of a transistor, the circuit CC₁ can determine which of the logical levels is to be output for each of the three circuits.

Likewise, the mask revision state output circuit CC₂, for example, has three circuits shown in FIG. 5. By changing a mask for forming the gate electrode of the transistor, the circuit CC₂ can determine which of the logical levels is to be output for each of the three circuits. Also, each of the mask revision state output circuits CC₂ to CCₖ₊₂ has three circuits shown in FIG. 5 or FIG. 7. By changing a mask for k layers forming the contact hole of the transistor, it is possible to determine which of the logical levels is to be output for each of the three circuits. Each of the mask revision state output circuits CCₖ₊₃ to CCₙ has three circuits as shown in FIG. 9 or FIG. 11. By changing a mask for (k+1) layers forming the wiring of the transistor, it is possible to determine which of the logical levels is to be output for each of the three circuits.

On the other hand, the EXOR circuit 21 conducts an EXOR arithmetic operation to the first-bit output value output from each of the mask revision state output circuits CC₁ to CC₁ stated above, i.e., to input data of n bits and outputs the operation result as a register value. Likewise, the EXOR circuit 22 conducts an EXOR arithmetic operation to the second-bit output value output from each of the mask revision state output circuits CC₁ to CCₙ and outputs the operation result as a register value. The EXOR circuit 23 conducts an EXOR arithmetic operation to the third-bit output value output from each of the mask revision state output circuits CC₁ to CCₙ and outputs the operation result as a register value.

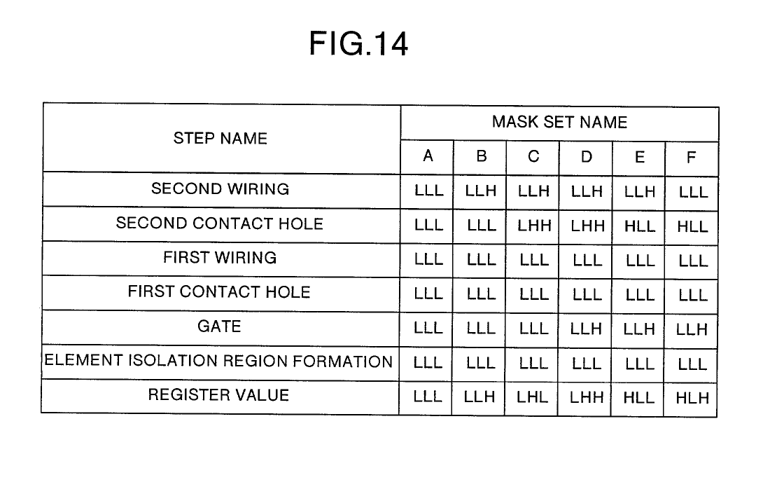

Operation of the version management circuit in the second embodiment will now be described with reference to FIG. 14. The table of FIG. 14 particularly shows a case where this version management circuit is applied to a 2-layer, 1-poly CMOS device. The second wiring mask, the second contact hole mask, the first wiring mask, the first contact hole mask, a gate formation mask and an element isolation region formation mask are used to manufacture the 2-layer, 1-poly CMOS device.

Description will be given while taking a case where the second wiring mask, the second contact hole mask, the gate formation mask, the second contact hole mask and the second wiring mask are revised in this order as an example. It is assumed that an initial mask set is A, followed by B, C, D, E and F which are the names of mask sets for which following revisions are executed.

Further, the mask revision state output circuits CC₁, CC₂, CC₃, CC₄, CC₅ and CC₆ correspond to circuits which output values are determined by the changes of only the second wiring mask, the second contact hole mask, the first wiring mask, the first contact hole mask, the gate formation mask and the element isolation region formation mask, respectively.

First, with the initial mask set (or mask set A) to which no revision is made, if it is assumed that the logical levels of the output values of the mask revision state output circuits CC₁ to CC₆ are all “LLL”, each of the EXOR circuits 21, 22 and 23 receives the output values of the mask revision state output circuits CC₁ to CC₈ and consequently outputs a logical level “L”. Namely, each of the EXOR circuits 21, 22 and 23 outputs, as a register value, 3-bit data “LLL”. If it becomes necessary to revise the semiconductor integrated circuit, the pattern of apart of the second wiring mask which part constitutes at least the mask revision state output circuit CC₁ is changed from the state of the mask set A (to that of the mask set B), thereby changing the logical level of output value of the mask revision state output circuit CC₁ from “LLL” to “LLH”. By changing so, each of the EXOR circuits 21, 22 and 23 outputs, as a register value, a logical level “LLH”.

If it becomes further necessary to revise the semiconductor integrated circuit, the pattern of the part of the second contact hole mask which part constitutes at least the mask revision state output circuit CC₂ is changed from the state of the mask set B described above (to that of the mask set C), thereby changing the logical level of the mask revision state output value CC₂ from “LLL” to “LHH”. By changing so, each of the EXOR circuits 21, 22 and 23 outputs, as a register value, a logical level “LHL”.

Further, if it becomes necessary to revise the semiconductor integrated circuit, the pattern of the part of the gate formation mask which constitutes at least the mask revision state output circuit CC₃ is changed from the state of the mask set C described above (to that of the mask set D), thereby changing the logical level of the output value of the mask revise state output circuit CC₃ from “LLL” to “LLH”. By changing so, each of the EXOR circuits 21, 22 and 23 outputs, as a register value, a logical level “LHH”.

Likewise, the patterns of the masks are changed so that the output values have logical levels as shown in FIG. 14 for the mask sets D, E and F, thereby making it possible to change the register values. By referring to the register values, it is possible to specify a mask set during a revision.

As stated so far, according to the version management circuit and the manufacturing method therefor in the second embodiment, each mask revision state output circuit described in the first embodiment is constituted to output values of plural bits by changing masks and EXOR circuits corresponding to the plural bits are provided, thereby making it possible to obtain register values of plural bits. Due to this, it is possible to specify a mask set, i.e., a version code from the numeric values indicating the register values and to execute more detailed version management for revising the semiconductor integrated circuit.

In the second embodiment, even if the version management mask is constituted such that the EXOR circuits 21, 22 and 23 are eliminated and that only one of the mask revision state output circuits CC₁ to CC₆ is provided, the above-stated advantages can be obtained. In the latter case, the output value output from the mask revision state output circuit serves as revision information indicating a version code.

As stated so far, according to the present invention can advantageously change the version management circuit, rewrite the version code and consequently reduce mask cost by changing only the mask related to a circuit which is required to be changed or by even changing one mask other than the mask related to the circuit which is required to be changed.

Furthermore, it is advantageously possible to realize the management of the revision information on the semiconductor integrated circuit by the version management circuit no matter which mask in the element isolation region formation step, the contact hole formation step or the wiring formation step is changed.

Moreover, even if the MOS transistor determining the output value of the mask revision state output units is in an invalid state in which the MOS transistor cannot carry out transistor operation or the like, it is advantageously possible to stably obtain the output value of a predetermined logical level from the mask revision state output units.

Furthermore, it is advantageously possible to stably obtain the output value of a predetermined logical level from the mask revision state output units even if the MOS transistor determining the output value of the mask revision state output units is turned in an invalid state because of the formation of the element isolation region on the gate section of the MOS transistor.

Moreover, it is advantageously possible to stably obtain the output value of a predetermined logical level from the mask revision state output units even if the MOS transistor determining the output value of the mask revision state output units is turned in an invalid state in which the source electrode is not connected to either the ground line or the power supply voltage line.

Furthermore, it is advantageously possible to stably obtain the output value of the second logical level from the mask revision state output units even if the MOS transistor determining the output value of the mask revision state output units turned in an invalid state in which the source electrode is not connected to the ground line or the power supply voltage line.

Moreover, it is advantageously possible to stably obtain the output value of the first logical level or the second logical level from the mask revision state output mans by the output wiring connected to the ground line or the power supply voltage line through the contact hole.

Furthermore, it is advantageously possible to stably obtain the output value of the first logical level or the second logical level from the mask revision state output mans by the output wiring connected to the ground line or the power supply voltage line on the same layer.

Moreover, according to the present invention, it is advantageously possible to manufacture a version management circuit capable of changing the version information on the semiconductor integrated circuit by changing only the pattern of any one of a plurality of masks used in the photolithographic step.

Furthermore, it is advantageously possible to manufacture a version management circuit capable of changing the revision information on the semiconductor integrated circuit no matter which mask in the element isolation region formation step, the contact formation step or the wiring formation step is changed.

Moreover, it is advantageously possible to change the revision information on the semiconductor integrated circuit by turning the MOS transistor determining the revision information in an invalid state by forming the element isolation region on the gate section of the MOS transistor.

Furthermore, it is advantageously possible to change the revision information on the semiconductor integrated circuit by turning the MOS transistor determining the revision information in an invalid state by not connecting the source electrode of the MOS transistor to the ground line or the power supply voltage line.

Moreover, it is advantageously possible to change the revision information on the semiconductor integrated circuit by turning the MOS transistor determining the revision information in an invalid state by not connecting the source electrode of the MOS transistor to the ground line or the power supply voltage line.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A version management circuit formed by sharing a part of a photolithographic technique by which a semiconductor integrated circuit is formed, said version management circuit holding revision information on the semiconductor integrated circuit, said version management circuit comprising:
a plurality of mask revision state output units which change different output values according to changes by each being formed by changing a part of a pattern of one of a plurality of masks used in the photolithographic technique to a pattern having a masked part or a non-masked part; and
a revision information generation unit which generates the revision information on said semiconductor integrated circuit based on the output values output from said plurality of mask revision state output units.

2. The version management circuit according to claim 1, wherein any one of the plurality of masks used in the photolithographic technique is a mask used in one of an element isolation region formation step, a contact hole formation step and a wiring formation step.

3. The version management circuit according to claim 1, wherein
at least one of said plurality of mask revision state output units comprises at least one MOS transistor turned on by an enable signal; and
at least one of said plurality of mask revision state output units outputs an output value of a first logical level if said MOS transistor is turned on, and outputs an output value of a second logical level if said MOS transistor is turned off or in an invalid state.

4. The version management circuit according to claim 3, wherein an element isolation region is formed on a gate section of said MOS transistor, and said MOS transistor is in the invalid state.

5. The version management circuit according to claim 3, wherein a contact hole connecting a source electrode of said MOS transistor to one of a ground line and a power supply voltage line is not provided, and the MOS transistor is in the invalid state.

6. The version management circuit according to claim 3, wherein a wiring connecting a source electrode of said MOS transistor to one of a ground line and a power supply voltage line is cut off, and the output value of the second logical level is output.

7. The version management circuit according to claim 1, wherein
any one of said plurality of mask revision state output units comprises at least one output wiring connected to one of a ground line and a power supply voltage line through a contact hole; and
the output value of one of a first logical level and a second logical level is output from said output wiring.

8. The version management circuit according to claim 1, wherein
any one of said plurality of mask revision state output units comprises at least one output wiring connected to one of a ground line and a power supply line on a same layer; and
the output value of one of a first logical level and a second logical level is output from said output wiring.

9. A method of manufacturing a version management circuit, said version management circuit formed by sharing a part of a photolithographic technique by which a semiconductor integrated circuit is formed, said version management circuit holding revision information on the semiconductor integrated circuit, the method comprising:
a mask change step of changing a part of a pattern of any one of a plurality of masks used in the photolithographic technique to one of a masked part and a non-masked part, said part determining an output value of said version management circuit; and
a version management circuit formation step of forming said version management circuit using the mask changed in said mask change step.

10. The method according to claim 9, wherein any one of the plurality of masks used in the photolithographic technique is a mask used in one of an element isolation region formation step, a contact hole formation step and a wiring formation step.

11. The method according to claim 9, wherein
in said mask change step, if said semiconductor integrated circuit is revised, a pattern of the mask used in an element isolation region formation step for said semiconductor integrated circuit is changed to a pattern for forming an element isolation region on a gate section of an MOS transistor determining the output value of said version management circuit.

12. The method according to claim 9, wherein
in said mask change step, if said semiconductor integrated circuit is revised, a pattern of the mask used in a contact hole formation step for said semiconductor integrated circuit is changed to a pattern for not forming a contact hole connecting a source electrode of an MOS transistor determining the output value of said version management circuit to one of a ground line and a power supply voltage line.

13. The method according to claim 9, wherein
in said mask change step, if said semiconductor integrated circuit is revised, a pattern of the mask used in a wiring formation step for said semiconductor integrated circuit is changed to a pattern for forming a wiring connecting a source electrode of an MOS transistor determining the output value of said version management circuit to one of a ground line and a power supply voltage line.
